(19) United States
(12) Patent Application Publication
(10) Pub. No.: US 2024/0071864 A1
(43) Pub. Date: Feb. 29, 2024

(54) SEMICONDUCTOR STRUCTURE, FORMING METHOD OF SAME AND MEMORY

(71) Applicant: CHANGXIN MEMORY TECHNOLOGIES, INC., Hefei City (CN)

(72) Inventor: Kaimin LV, Hefei (CN)

(73) Assignee: CHANGXIN MEMORY TECHNOLOGIES, INC., Hefei City (CN)

(21) Appl. No.: 18/161,088

(22) Filed: Jan. 29, 2023

(30) Foreign Application Priority Data
Aug. 26, 2022 (CN) 202211033881.8

(51) Int. Cl. H01L 23/42; H01L 23/00; H01L 25/00; H10B 80/00

(52) U.S. Cl. CPC H01L 23/42; H01L 24/16; H01L 24/32; H01L 24/73; H01L 25/50; H10B 80/00; H01L 2224/16145; H01L 2224/16227; H01L 2224/32145; H01L 2224/32225; H01L 2224/73204

(57) ABSTRACT

A semiconductor structure includes a base, a chipset and a heat conduction adjusting layer. The chipset is disposed at one side of the base and includes multiple chip units arranged at intervals along a direction perpendicular to the base. Each of the chip units includes a substrate and a circuit module disposed on a surface of the substrate. The substrate includes a circuit interconnection region and a non-circuit interconnection region distributed adjacently. The circuit module is disposed on a surface of the circuit interconnection region, and adjacent chip units are electrically connected by the circuit module. The heat conduction adjusting layer is in contact with at least one of the substrates for reducing the difference of heat conduction rates between surfaces of the substrates.

### CROSS-REFERENCE TO RELATED APPLICATION

The present disclosure claims priority to Chinese Patent Application No. 202211033881.8 filed on Aug. 26, 2022, the disclosure of which is hereby incorporated by reference in its entirety.

### BACKGROUND

A memory is widely used in mobile devices such as mobile phones and tablet computers because of its small size, high integration and fast transmission speed. In order to improve the storage capacity of the memory, it is usually necessary to superimpose multiple chip units.

At present, the chip units are mainly stacked by thermal compression bond (TCB). However, with the increase of layers of chip units, poor welding between the chip units is easy to occur in the TCB process, so that the product yield is low.

It is to be noted that the information disclosed in the above background is only for enhancement of understanding of the background of the disclosure, and therefore may include information that does not constitute the related art known to a person of ordinary skill in the art.

### SUMMARY

The disclosure relates to the technical field of semiconductors, in particular to a semiconductor structure, a forming method of the same and a memory.

In view of this, the disclosure provides a semiconductor structure, a forming method of the same and a memory.

According to one aspect of the disclosure, a semiconductor structure is provided, including a base, a chipset and a heat conduction adjusting layer.

The chipset is disposed at one side of the base, and includes multiple chip units arranged at intervals along a direction perpendicular to the base. Each of the chip units includes a substrate and a circuit module disposed on a surface of the substrate. The substrate includes a circuit interconnection region and a non-circuit interconnection region distributed adjacently. The circuit module is disposed on a surface of the circuit interconnection region. Two adjacent ones of the chip units are electrically connected through the circuit module.

The heat conduction adjusting layer is in contact with at least one of the substrates for reducing difference of heat conduction rates between surfaces of the substrates.

According to another aspect of the disclosure, a forming method of a semiconductor structure is provided. The method includes the following operations.

Abase is provided.

A chipset is formed at one side of the base. The chipset includes multiple chip units arranged at intervals along a direction perpendicular to the base. Each of the chip units includes a substrate and a circuit module disposed on a surface of the substrate. The substrate includes a circuit interconnection region and a non-circuit interconnection region distributed adjacently. The circuit module is disposed on a surface of the circuit interconnection region, and two adjacent ones of the chip units are electrically connected through the circuit module.

A heat conduction adjusting layer is formed at one side of at least one of the substrates. The heat conduction adjusting layer is in contact with the at least one of the substrates for reducing difference of heat conduction rates between surfaces of the substrates.

The chipset including the heat conduction adjusting layer is connected fixedly with the base by a thermal compression bond process.

According to yet another aspect of the present disclosure, a memory is provided. The memory includes the semiconductor structures according to any one of the above embodiments.

It should be understood that the above general description and the following detailed description are only exemplary and explanatory in nature, and the disclosure is not limited thereto.

### BRIEF DESCRIPTION OF THE DRAWINGS

The drawings herein, which are incorporated in and form a part of the specification, show embodiments consistent with the disclosure and serve to explain the principles of the disclosure together with the description. It is apparent that the drawings described below are only of some embodiments of the disclosure, from which other drawings may be obtained without creative effort by a person of ordinary skill in the art.

FIG. 1 is a schematic diagram of a semiconductor structure provided by an embodiment of the disclosure;

FIG. 2 is a schematic diagram of a semiconductor structure provided by an embodiment of the disclosure;

FIG. 3 is a schematic diagram of a semiconductor structure provided by an embodiment of the disclosure;

FIG. 4 is a schematic diagram of a semiconductor structure provided by an embodiment of the disclosure;

FIG. 5 is a schematic diagram of a semiconductor structure provided by an embodiment of the disclosure;

FIG. 6 is a schematic diagram of a semiconductor structure provided by an embodiment of the disclosure;

FIG. 7 is a schematic diagram of the conductive structure and the connecting pad in an embodiment of the disclosure;

FIG. 8 is a top view of the heat conduction adjusting layer in an embodiment of the disclosure; and

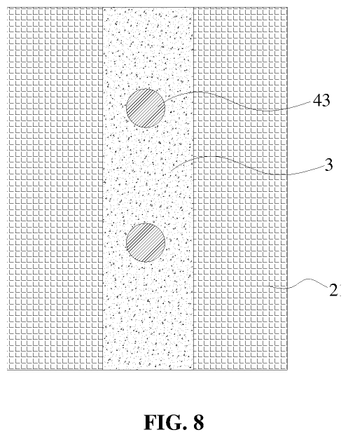

FIG. 9 is a flowchart showing a forming method of a semiconductor structure in an embodiment of the disclosure.

### DETAILED DESCRIPTION

The exemplary embodiments are described more fully with reference to the accompany drawings. However, the exemplary embodiments can be implemented in various forms and should not be construed as limited to the embodiments set forth herein. Rather, these embodiments are provided for the purpose that the disclosure will be thorough and complete, and the concept of the exemplary embodiments will be fully conveyed to those skilled in the art. The same reference numerals in the drawings denote the same or similar structures, and thus their detailed description will be omitted. In addition, the accompany drawings are only schematic illustrations of the disclosure, and are not necessarily drawn to scale.

Although relative terms such as “upper” and “lower” are used in the specification to describe a relative relationship of one component to another component shown in the drawing, these terms are used in the specification only for convenience, for example according to the exemplary direction described in the accompany drawings. Understandably, if a device shown in the drawing is flipped upside down, the component described “upper” will become the component described “lower”. When a structure is “on” another structure, it may mean that the structure is integrally formed on another structure, or that the structure is “directly” on another structure, or that the structure is “indirectly” arranged on another structure through yet another structure.

The terms “a”, “an”, “the”, “said” and “at least one” are used to indicate the presence of one or more elements/components/etc. The terms “include/comprise” and “have” indicate an open-ended inclusion and mean that additional elements/components/etc. may be present in addition to the listed elements/components/etc. The terms “first” and “second” or the like are used only as markers, and are not intending to limit the number of their objects.

In related art, a common memory mainly includes a base and chip units arranged on the base. In order to ensure the storage capacity of the memory, multiple chip units are usually stacked on the base. In the process, the adjacent chip units are usually electrically connected together by welding. However, in the welding process, with the increase of the number of the chip units, the heat conduction rate in the surface of a same chip unit is often uneven, or the heat conduction rates of different chip units are different in the direction perpendicular to the base, resulting in poor welding (for example, welding at a circuit interconnection region succeeds while welding at a non-circuit interconnection region fails, or welding of top chip units succeeds while welding of lower chip units fails), and further resulting in a product failure and a low product yield.

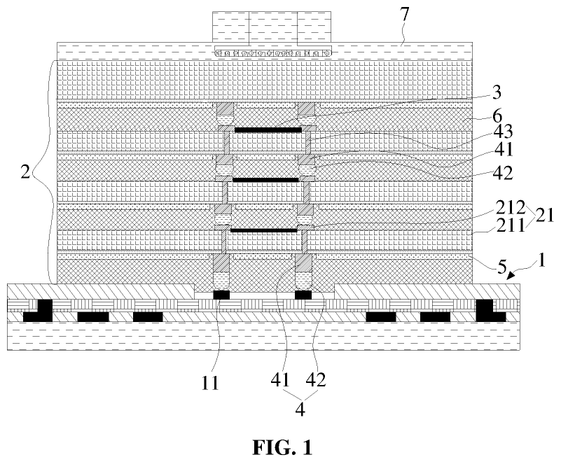

Embodiments of the disclosure provide a semiconductor structure. FIGS. 1-6 show the schematic diagrams of the semiconductor structures of the disclosure. Referring to FIGS. 1-6, the semiconductor structure may include a base 1, a chipset 2, and a heat conduction adjusting layer 3.

The chipset 2 is located at one side of the base 1, and includes multiple chip units 21 arranged at intervals along a direction perpendicular to the base 1. Each of the chip units 21 includes a substrate 211 and a circuit module 212 located on a surface of the substrate 211. The substrate 211 includes a circuit interconnection region and a non-circuit interconnection region arranged adjacently. The circuit module 212 is located on a surface of the circuit interconnection region. Two adjacent ones of the chip units 21 are electrically connected through the circuit modules 212.

The heat conduction adjusting layer 3 is in contact with at least one of the substrates 211 for reducing difference of heat conduction rates between surfaces of the substrates 211.

In the semiconductor structure provided by the disclosure, multiple chip units 21 are stacked in the vertical direction by thermal compression bond (TCB), which helps to improve the storage capacity. In the process, due to the contact between a heat conduction adjusting layer 3 and a substrate 211 in the chip unit 21, by providing the heat conduction adjusting layer 3 in the TCB process, the difference of heat conduction rates between surfaces of different substrates 211 can be reduced, or the difference of heat conduction rates between surfaces of different regions of a same substrate 211 can be reduced. Accordingly, the difference of heat conduction rates between the chip units 21 located in different layers can be reduced in the TCB welding process, thereby reducing the difference of temperatures between the surfaces of the chip units 21, reducing the probability of poor welding due to the different welding temperatures between different chip units 21, and further improving the product yield. Or, the difference of heat conduction rates between different regions of a same chip unit 21 can be reduced in the TCB welding process, thereby reducing the temperature difference of the surface of the same chip unit 21, reducing the probability of poor welding in different regions of the same chip unit 21, and further improving the product yield.

Specific details of the semiconductor structure of the disclosure are described in detail below.

The base 1 may have a flat structure, which may be rectangular, circular, elliptical, polygonal or irregular shape. The material of the base 1 may be a semiconductor material, for example, may be silicon, but is not limited to silicon or other semiconductor material. The shape and the material of the base 1 are not particularly limited herein.

The base 1 may include a central region and a peripheral region. The central region and the peripheral region may be arranged adjacent to each other. The peripheral region may surround the periphery of the central region. The central region may be configured to form the chipset 2 and the external circuit 11, and the peripheral region may be configured to form the external circuit 11. For example, the central region may be a circular region, a rectangular region, or an irregular shape region. The central region may also be a region of another shape, which is not particularly limited here. The peripheral region may be an annular region and may surround the outer circumference of the central region. The peripheral region may be a circular annular region, a rectangular annular region or an annular region of another shape, which is not enumerated herein.

The chipset 2 may be located on one side of base 1. For example, it may be located in the central region of the base 1. The chipset 2 may include multiple chip units 21. The chipset 2 may be used in an integrated circuit. For example, the chipset 2 may be used in a dynamic random access memory (DRAM) or a static random access memory (SRAM). In order to achieve a low driving voltage, the size of the DRAM or the SRAM should be reduced as much as possible. Since the chip units 21 are core components of a DRAM or a SRAM, in order to reduce the size of the DRAM or the SRAM meanwhile with ensuring the storage capacity, multiple chip units 21 may be stacked in the direction perpendicular to the base 1 to form the chipset 2. For example, the number of the chip units 21 in the chipset 2 may be 2, 3, 4, 5, 6, 7, or other number, which is not particularly limited herein.

In some embodiments of the disclosure, all the chip units 21 in the chipset 2 may be electrically connected, which facilitates the mutual transmission of data in multiple chip units 21, further facilitates the transmission of data from different chip units 21 to a same chip unit 21, so that electrical signal of each chip unit 21 in the chipset 2 can be transmitted to the base 1 through a same chip unit 21 simultaneously, so as to connect each chip unit 21 to the external circuit 11, thereby realizing signal transmission.

In some embodiments of the disclosure, the chip units 21 in the chipset 2 may be arranged at intervals in the direction perpendicular to the base 1. For example, the chip units 21 may be equally spaced in the direction perpendicular to the base 1. For example, the chip units 21 may be spaced in a preset distance. The spacing distance between the chip units 21 may not be equal. For example, for multiple chip units 21, a spacing distance between at least two of the chip units 21 is not equal to a spacing distance between other adjacent two of the chip units 21.

In some embodiments of the disclosure, the preset distance may be 10 μm to 150 μm. For example, the preset distance may be 10 μm, 40 μm, 70 μm, 100 μm, 130 μm or 150 μm. Of course the preset distance may be other values, which is not enumerated herein.

In an exemplary embodiment of the disclosure, the chip units 21 may have a sheet-like structure, which may have a shape of rectangular, circular, oval, or irregular, without particular limitation herein. The thickness of each chip unit 21 may be the same or different, without particular limitation herein. The thickness of the chip unit 21 may be from 40 μm to 80 μm. For example, it may be 40 μm, 50 μm, 60 μm, 70 μm, 80 μm, or other thicknesses, which is not enumerated herein.

In some embodiments of the disclosure, each of the chip units 21 in the chipset 2 may have a same thickness. For example, each chip unit 21 may have a thickness of 50 μm, or each chip unit 21 may have a thickness of 60 μm, or each chip unit 21 may have a thickness of 70 μm. Of course each chip unit 21 may also have other thickness, which is not enumerated herein.

In an exemplary embodiment of the disclosure, each of the chip units 21 may include a substrate 211 and a circuit module 212. The substrate 211 may include a circuit interconnection region and a non-circuit interconnection region distributed adjacently. The circuit interconnection region may be a circular region, a rectangular region or an irregular-shape region. Of course it may be a region of other shape, which is not particularly limited here. The non-circuit interconnection region may be an annular region and may surround the periphery of the circuit interconnection region. The non-circuit interconnection region may be a circular annular region, a rectangular annular region or an annular region of other shape, which is not enumerated herein.

In an exemplary embodiment of the disclosure, the circuit module 212 may be located on the surface of substrate 211. For example, the circuit module 212 may be located on the surface of the circuit interconnection region. For example, the circuit module 212 may be located on a surface of the substrate 211 of each chip unit 21 away from the base 1. In some embodiments of the disclosure, the adjacent chip units 21 in the chipset 2 may be electrically connected through the circuit modules 212.

As shown in FIGS. 1-7, the heat conduction adjusting layer 3 may be in contact with at least one of the substrates 211. The heat conduction adjusting layer 3 may be located on a side of the substrate 211 near the base 1 or on a side of the substrate 211 away from the base 1, without particular limitation herein. By providing the heat conduction adjusting layer 3, the difference of heat conduction rates between surfaces of different substrates 211 can be reduced, or the difference of heat conduction rates between surfaces in different regions in a same substrate 211 can be reduced, so that the difference of heat conduction rates between the chip units 21 located in different layers can be reduced in the TCB welding process, thereby reducing the difference of temperatures of the surfaces of the chip units 21, reducing the probability of poor welding due to the different welding temperatures between different chip units 21, and further improving the product yield. Alternatively, difference of heat conduction rates between different regions of a same chip unit 21 in the TCB welding process can be reduced, thereby reducing the temperature difference on the surface of the same chip unit 21, reducing the probability of poor welding in different regions of the same chip unit 21, and further improving the product yield.

In an exemplary embodiment of the disclosure, the heat conduction adjusting layer 3 may be located on the side of the substrate 211 away from the base 1 and may be arranged side-by-side with the circuit module 212 located on the surface of the substrate 211. The difference of heat conduction rates between the circuit interconnection region and the non-circuit interconnection region may be reduced by the heat conduction adjusting layer 3. The heat conduction adjusting layer 3 may be a thin film formed on the surface of the substrate 211 away from the base 1 or a coating formed on the surface of the substrate 211 away from the base 1. A specific form of the heat conduction adjusting layer 3 is not specifically limited herein.

The thickness of the heat conduction adjusting layer 3 may be 100 nm to 5000 nm. For example, the thickness of the heat conduction adjusting layer 3 may be 100 nm, 500 nm, 1000 nm, 2000 nm, 3000 nm, 4000 nm or 5000 nm. Of course the thickness of the heat conduction adjusting layer 3 may have other thickness, which is not enumerated herein.

Specific details of the arrangement of the heat conduction adjusting layer 3 are described in detail through the following three embodiments.

In a first embodiment of the disclosure, as shown in FIG. 1, the material of the heat conduction adjusting layer 3 may be a material with a relatively low heat conduction rate. For example, the material may be a non-metallic material. The heat conduction adjusting layer 3 may be located in the circuit interconnection region of the substrate 211 of each of the chip units 21. The heat conduction rate of the heat conduction adjusting layer 3 may be lower than the heat conduction rate of the circuit interconnection region of the substrate 211. The heat conduction rate of the circuit interconnection region can be reduced by providing the heat conduction adjusting layer 3 with a relatively low heat conduction rate. Therefore, the problem of uneven welding temperature of the surface of a same chip unit 21 caused by a greater heat conduction rate in the circuit interconnection region and a lower heat conduction rate in the non-circuit interconnection region is mitigated, further avoiding successful welding of some regions and poor welding of other regions in the same chip unit 21, which can improve the product yield.

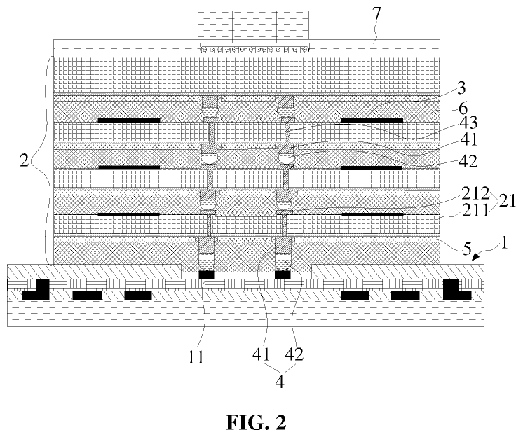

In a second embodiment of the disclosure, as shown in FIG. 2, the material of the heat conduction adjusting layer 3 may be a material with a relatively high heat conduction rate. For example, the material may include one or more carbon allotropes, such as diamond, graphene, graphite, carbon nanotube, or combinations thereof. Alternatively, the material of the heat conduction adjusting layer 3 may be a metal and an alloy material thereof. The heat conduction adjusting layer 3 may be located in a non-circuit interconnection region of the substrate 211 of each of the chip units 21. The heat conduction rate of the heat conduction adjusting layer 3 may be greater than the heat conduction rate of the non-circuit interconnection region of the substrate 211. The heat conduction rate of the non-circuit interconnection region can be increased by providing the heat conduction adjusting layer 3 with a relatively high heat conduction rate. Therefore, the problem of uneven welding temperature of the surface of a same chip unit 21 caused by a greater heat conduction rate in the circuit interconnection region and a lower heat conduction rate in the non-circuit interconnection region is mitigated, and further avoiding successful welding of some regions and poor welding of other regions in the same chip unit 21, which can improve the product yield.

It is to be noted that, the surface of the substrate 211 in each of the chip units 21 of the chipset 2 may be provided with a layer of the above-mentioned heat conduction adjusting layer 3. Or, the surfaces of the substrates 211 in part of the chip units 21 of the chipset 2 may be provided with a layer of the above-mentioned heat conduction adjusting layer 3. For example, the heat conduction adjusting layer 3 may be provided on the surface of the substrate 211 in each of the chip units 21 farther away from the base 1, but may not be provided on the surface of the substrate 211 in each of the chip units 21 closer to the base 1.

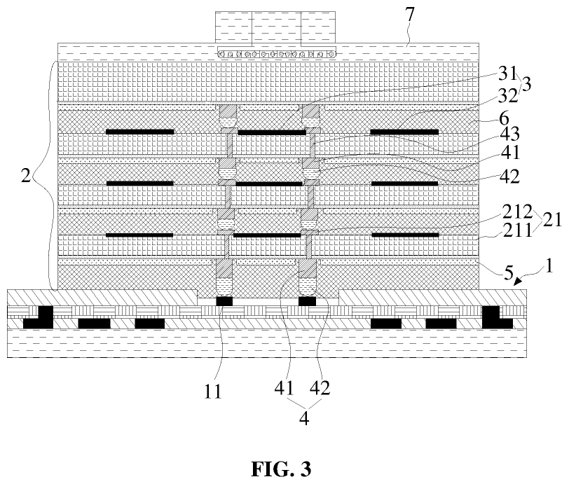

In a third embodiment of the disclosure, as shown in FIG. 3, the heat conduction adjusting layer 3 may include a first adjusting part 31 and a second adjusting part 32. Orthographic projections of the first adjusting part 31 and the second adjusting part 32 on the base 1 do not overlap with each other. For example, as shown in FIG. 3, the first adjusting part 31 may be located on the surface of the circuit interconnection region of the substrate 211, and may be in contact with the circuit interconnection region 211 of the substrate. The heat conduction rate of the first adjusting part 31 may be lower than the heat conduction rate of the circuit interconnection region, so that the heat conduction rate of the circuit interconnection region of the chip unit 21 may be reduced by the first adjusting part 31. The second adjusting part 32 may be located on the surface of the non-circuit interconnection region of the substrate 211, and may be in contact with the non-circuit interconnection region of substrate 211. The heat conduction rate of the second adjusting part 32 may be greater than the heat conduction rate of the non-circuit interconnection region of the substrate 211, and the heat conduction rate of the second adjusting part 32 may be greater than the heat conduction rate of the first adjusting part 31. The heat conduction rate of the non-circuit interconnection region of the chip unit 21 may be increased by the second adjusting part 32. In the embodiment, the heat conduction rates of different regions of the substrate 211 can be rapidly equalized by a cooperation of the first adjusting part 31 and the second adjusting part 32, thereby achieving rapid temperature equalization during the TCB welding process and further reducing the probability of poor welding.

It is to be noted that, the surface of the substrate 211 in each of the chip units 21 of the chipset 2 may be provided with a layer of the above-mentioned first adjusting part 31 and second adjusting part 32, or the surfaces of the substrates of part of the chip units 21 of the chipset 2 may be provided with a layer of the above-mentioned first adjusting part 31 and second adjusting part 32. For example, the first adjusting part 31 and second adjusting part 32 may be provided on the surface of the substrate 211 in each of the chip units 21 farther away from the base 1, but not be provided on the surface of the substrate 211 in each of the chip units 21 closer to the base 1.

In an exemplary embodiment of the disclosure, the heat conduction adjusting layers 3 may be in contact with the surface of the substrate 211 far away from the base 1. The difference of the heat conduction rates between the chip units 21 in different layers can be reduced through the heat conduction adjusting layers 3, thereby reducing the difference of temperatures of the surfaces of the chip units 21, reducing the probability of poor welding due to different welding temperatures between the different chip units 21, and further improving the product yield.

Specific details of the arrangement of the heat conduction adjusting layer 3 are described in detail through the following three embodiments.

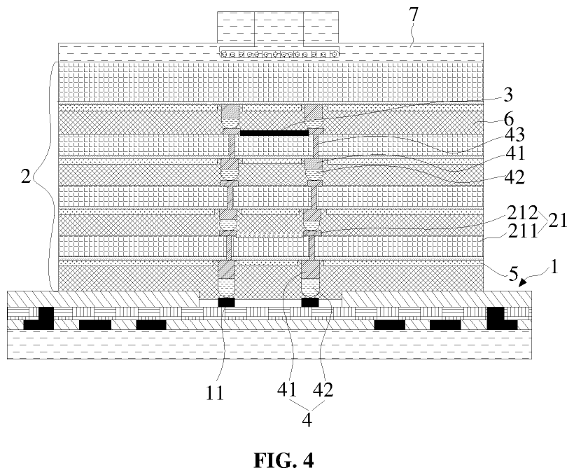

In a fourth embodiment of the disclosure, the material of the heat conduction adjusting layer 3 may be a material with a relatively low heat conduction rate. For example, the material may be a non-metallic material. As shown in FIG. 4, the heat conduction adjusting layer 3 may be located on the surface of a chip unit 21 farther away from the base 1. For example, the heat conduction adjusting layer 3 may at least be located on the surface of the circuit interconnection region 21 in the chip unit farthest away from the base 1, and the heat conduction rate of the heat conduction adjusting layer 3 may be lower than the heat conduction rate of the substrate 211 of the chip unit 21 farthest away from base 1. By providing a heat conduction adjusting layer 3 with a relatively low heat conduction rate on the surface of the chip unit 21 farther away from the base 1, the heat conduction rate of the surface of the chip unit 21 farther away from the base 1 is reduced, and the difference of heat conduction rates between the circuit interconnection regions of the chip units 21 in different layers is reduced, so as to avoid poor welding caused by high temperature of the chip units 21 located in upper layers and low temperature of the chip units 21 located in lower layers in the TCB welding process.

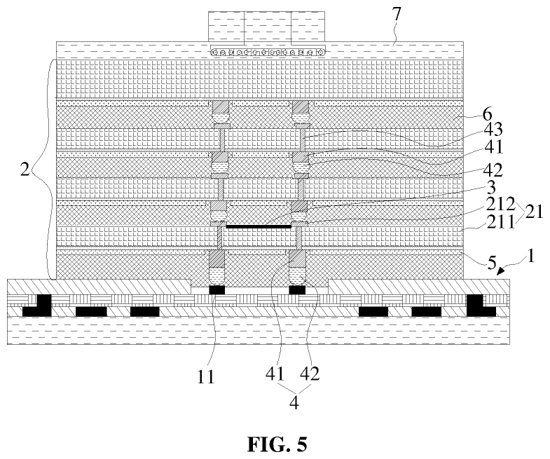

In a fifth embodiment of the disclosure, the material of the heat conduction adjusting layer 3 may be a material with a relatively high heat conduction rate. For example, the material may be a metallic material or an alloy material. As shown in FIG. 5, the heat conduction adjusting layer 3 may be located on the surface of the circuit interconnection region of a chip unit 21 closer to the base 1. For example, the heat conduction adjusting layer 3 may at least be located on the surface of the circuit interconnection region 21 in the chip unit closest to the base 1, and the heat conduction rate of the heat conduction adjusting layer 3 may be greater than the heat conduction rate of the circuit interconnection region in the substrate 211 of the chip unit 21 closest to the base 1. By providing a heat conduction adjusting layer 3 with a relatively high heat conduction rate on the surface of the chip unit 21 closer to the base 1, the heat conduction rate of the surface of the chip unit 21 closer to the base 1 is increased, and the difference of the heat conduction rates between the circuit interconnection regions of the chip units 21 in different layers is reduced, so as to avoid poor welding caused by high temperature of the chip units 21 located in upper layers and low temperature of the chip units 21 located in lower layers in the TCB welding process.

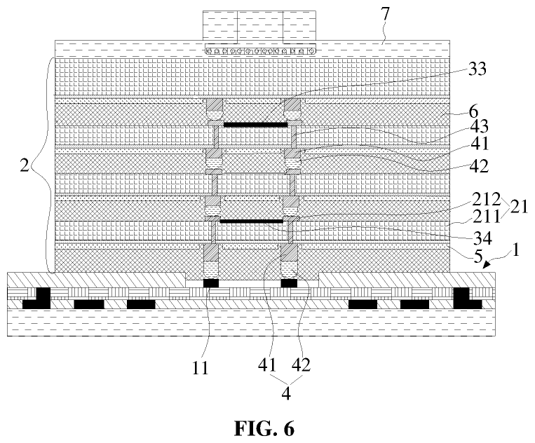

In a sixth embodiment of the disclosure, as shown in FIG. 6, the heat conduction adjusting layer 3 may include a third adjusting part 33 and a fourth adjusting part 34. For example, the third adjusting part 33 may at least be located on the surface of the circuit interconnection region 211 of the substrate of the chip unit 21 farthest away from the base 1. The heat conduction rate of the third adjusting part 33 may be lower than the heat conduction rate of the circuit interconnection region of the substrate 211 of the chip unit 21 farthest away from the base 1. The heat conduction rate of the circuit interconnection region of the chip unit 21 may be reduced by the third adjusting part 33. The fourth adjusting part 34 may at least be located on the surface of the circuit interconnection region of the substrate 211 of the chip unit 21 closest to the base 1. The heat conduction rate of the fourth adjusting part 34 may be greater than the heat conduction rate of the circuit interconnection region of the substrate 211 of the chip unit 21 closest to the base 1, and the heat conduction rate of the fourth adjusting part 34 may be greater than the heat conduction rate of the third adjusting part 33. The heat conduction rate of the circuit interconnection region of the substrate 211 of the chip unit 21 closest to the base 1 can be increased by the fourth adjusting part 34. According to the embodiment, the heat conduction rates of the chip units 21 in different layers can be quickly equalized by a cooperation of the third adjusting part 33 and the fourth adjusting part 34, and the temperatures of the chip units 21 in different layers can be quickly equalized during the TCB welding process, thereby further reducing the probability of poor welding.

Optionally, the surface of the circuit interconnection region of the substrate 211 in each of the chip unit 21 of the chipset 2 may be provided with a layer of the heat conduction adjusting layer 3 with a relatively lower heat conduction rate. In addition, in the direction perpendicular to base 1, with respect to any two adjacent chip units 21, the heat conduction rate of the heat conduction adjusting layer 3 away from the base 1 is smaller than that of the heat conduction adjusting layer 3 close to the base 1.

Optionally, the surface of the non-circuit interconnection region of the substrate 211 in each of the chip units 21 of the chipset 2 may be provided with a layer of the heat conduction adjusting layer 3 with a relatively higher heat conduction rate. In addition, in the direction perpendicular to base 1, with respect to any two adjacent chip units 21, the heat conduction rate of the heat conduction adjusting layer 3 away from the base 1 is lower than that of the heat conduction adjusting layer 3 on a side close to the base 1.

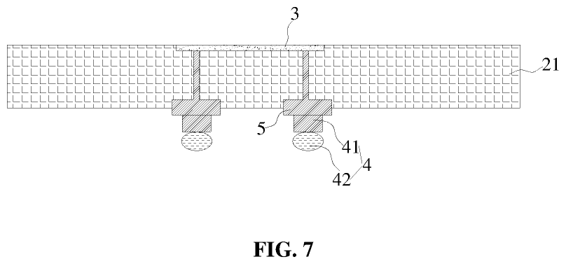

In some embodiments of the disclosure, referring further to FIG. 7, the heat conduction adjusting layer 3 may be embedded in the substrate 211, such that an adhesive layer 6 formed subsequently may be in close contact with a surface of each chip unit 21. For example, the surface of the substrate 211 facing away from the base 1 may be provided with a concave part depressed inwards in the direction perpendicular to the substrate 211, and the heat conduction adjusting layer 3 may at least be located within the concave part. The concave part may be formed in the substrate 211 by slotting. For example, the concave part may be formed by etching. The concave part may be formed in the circuit interconnection region of the substrate 211, or in the non-circuit interconnection region of the substrate 211. Or the concave parts may be formed in both the circuit interconnection region and the non-circuit interconnection region of the substrate 211, respectively. The concave part in the non-circuit interconnection region and the concave part in the circuit interconnection region may be connected or arranged at intervals, which is not particularly limited here.

The heat conduction adjusting layer 3 may be formed in the concave part by chemical vapor deposition, physical vapor deposition, or atomic layer deposition. Of course the heat conduction adjusting layer 3 may be formed by other means, which is not enumerated herein. The heat conduction adjusting layer 3 may fill up the concave part, and the surface of the heat conduction adjusting layer 3 may be flush with the top surface of the concave part or beyond the top surface of the concave part, without special limitation herein.

In other embodiments of the disclosure, the heat conduction adjusting layer 3 may be located on the surface of the substrate 211 facing away from the base 1. For example, the heat conduction adjusting layer 3 may be formed on the surface of the substrate 211 facing away from the base 1 by chemical vapor deposition, physical vapor deposition, or atomic layer deposition. Of course the heat conduction adjusting layer 3 may be formed by other means, which is not enumerated herein.

In some embodiments of the disclosure, continuing to refer to FIGS. 1-6, the base 1 may include an external circuit 11. The chipset 2 may be connected to the external circuit 11 in the base 1, so as to realize signal transmission. For example, the semiconductor structure of the disclosure may also include a conductive structure 4. The conductive structure 4 may at least be located between the chipset 2 and the base 1. The chipset 2 may be electrically connected to the external circuit 11 in the base 1 through the conductive structure 4. For example, one end of the conductive structure 4 may be connected to the circuit module 212 of any one of the chip units 21 in the chipset 2, and another end may be connected to the external circuit 11 in the base 1.

In some embodiments of the disclosure, the conductive structure 4 may include a connection pad 41 and a conductive bump 42. The connection pad 41 may be provided on the surface, close to the base 1, of the substrate 211 of the chip unit 21 closest to the base 1 in the chipset 2, and the surface may be disposed toward the base 1. The conductive bump 42 may be located between the connection pad 41 and the external circuit 11 of the base 1. Both ends of the conductive bump 42 may be in contact with the connection pad 41 and the external circuit 11, respectively.

The connection pad 41 may be made of a conductive material, such as gold, silver, copper, aluminum, tungsten or the like. In some embodiments of the disclosure, the connection pad 41 may be a solder pad formed on a surface of a chip unit 21. The connection pad 41 may be connected to the circuit module 212 on the surface of the substrate 211 of the chip unit 21 facing away from the base 1 through a through silicon via (TSV) 43. In other embodiments of the disclosure, the connection pad 41 may be a thin film or a coating formed on the surface of the chip unit 21, and a specific form of the connection pad 41 is not particularly limited herein. The connection pad 41 may be formed on the surface of the chip unit 21 by vacuum evaporation, magnetron sputtering, chemical vapor deposition, physical vapor deposition, or atomic layer deposition. Of course the connection pad 41 may be formed by other means, which is not specifically limited herein.

The conductive bump 42 may be provided on the surface of a corresponding connection pad 41 and may be in contact with the external circuit 11 of the base 1. The data signal in the circuit module 212 of the chip unit 21 may be transmitted to the external circuit 11 through the connection pad 41 and the conductive bumps 42. The conductive bump 42 may be made of a conductive material, for example, a solder material composed of one or more materials such as tin, lead, silver, copper, nickel, zinc, bismuth, indium, gold, cadmium, germanium, silicon, or the like. The shape of the conductive bump 42 may be hemispherical, spherical, elliptical, cylindrical, square, etc. In some embodiments of the disclosure, the conductive bump 42 may be a solder pad formed on the surface of the connection pad 41, which may be in contact with the external circuit 11 by soldering.

In some embodiments of the disclosure, conductive structures 4 may also be provided between the chip units 21. The chip units 21 may be electrically connected by the conductive structures 4. For example, a conductive structure 4 may be provided on the surface of each chip unit 21. In two adjacent ones of the chip units 21, the conductive bump 42 on the surface of the upper chip unit 21 may face the surface of the lower chip unit 21 away from the base 1, and may be in contact with the circuit module 212 of the lower chip unit 21, so that the data signal in the upper chip unit 21 is transmitted to the base 1 through the circuit module 212, the through silicon via (TSV) 43, the connection pad 41 and the conductive bump 42 on the lower chip unit 21. That is, the two adjacent chip units 21 may be electrically connected through the connection pad 41, the conductive bump 42, the circuit module 212, and the through silicon via (TSV) 43.

In some embodiments of the disclosure, multiple conductive structures 4 may be provided between two adjacent ones of the chip units 21. For example, two conductive structures 4 arranged at interval may be provided between the two adjacent chip units 21. The two conductive structures 4 may be located on both sides of the circuit interconnection area of the substrate 211, respectively. When the heat conduction adjusting layer 3 has a relatively low heat conduction rate, it may be provided between the two conductive structures 4. Alternatively, the heat conduction adjusting layer 3 may extend from the circuit interconnection region to the non-circuit interconnection region, and the heat conduction adjusting layer 3 may have an opening exposing the through-silicon path (TSV) 43 in the substrate 211. Through the TSV, the circuit module 212 may be connected to the conductive structure 4 of an upper chip unit 21.

In some embodiments of the disclosure, an insulating layer 5 may be provided on the surface of each chip unit 21. For example, the insulating layer 5 may be located on the side of the chip unit 21 near the base 1. The surface of the chip unit 21 may be insulated by the insulating layer 5 to avoid short circuit or coupling between the chip unit 21 and other conductive structures. In one embodiment, the material of insulating layer 5 may be silicon oxide, silicon nitride or the like. It is to be noted that, the insulating layer 5 may have openings exposing the conductive structures 4. The orthographic projections of the conductive structures 4 and the insulating layer 5 on the chip unit 21 do not overlap.

The number of the insulating layers 5 may match the number of gaps between the chip units 21. For example, the number of the insulating layers 5 is 1 less than that the number of the chip units 21 in the chipset 2. The insulating layers 5 may be arranged between two adjacent chip units 21 in one-to-one correspondence. The thickness of each insulating layer 5 may be equal to the distance between two adjacent chip units 21, that is, the insulating layer 5 may fill up the gap between the adjacent chip units 21.

In some embodiments of the disclosure, the semiconductor structure of the disclosure may also include an adhesive layer 6 by which two adjacent ones of the chip units 21 may be bonded together. In this process, the adjacent chip units 21 may be insulated by the adhesive layer 6 to avoid signal crosstalk or coupling between the chip units 21.

In an exemplary embodiment of the disclosure, the material of the adhesive layer 6 may be an adhesive, for example, it may be a non-conductive polymer (NCF or ACF), a quick-drying adhesive or a non-conductive adhesive, etc. External water and oxygen can be isolated by the adhesive layer 6, to prevent from entering the chip units 21, and further avoid from eroding the internal structure of the chip units 21, thereby prolonging the service life of the chip units 21.

In some embodiments of the disclosure, the adhesive layer 6 may fill up the gap between two adjacent one of the chip units 21. The gaps between the adjacent chip units 21 may be supported by the adhesive layer 6. Meanwhile the adhesive layer 6 can balance the stress between two adjacent chip units 21, which can reduce the possibility of fracture of the chip units 21 under external force, and can improve the product yield.

In some embodiments of the disclosure, the adhesive layer 6 in the chipset 2 may be a thick layer, so that the chip units 21 may be embedded in the adhesive layer 6. For example, after the chipset 2 is formed, the adhesive layer 6 may be formed on surfaces of the structure composed of the base 1 and the chipset 2. The adhesive layer 6 may fill up the gaps between the chip units 21 and cover the sidewalls of the chip units 21, thereby realizing all-round isolation and protection of the chip units 21.

In other embodiments of the disclosure, the adhesive layer 6 may include a plurality of insulating filling layers distributed at intervals. The insulating filling layers and the chipset 2 are fixed on the base 1 to constitute a structure, then surfaces of the structure composed of the insulating filling layers, the chipset 2 and the base 1 may be further covered with the insulating material, so that the chipset 2 may be buried in the insulating material. The insulating material and the insulating filling layers may jointly form the adhesive layer 6. The insulating material and the material of the insulating filling layers may be the same or different, which is not particularly limited herein. For example, the insulating material and the material of the insulating filling layers may be both of NCF.

In an exemplary embodiment of the disclosure, when the heat conduction adjusting layer 3 is located in the circuit interconnection region of the substrate 211, the heat conduction rate of the heat conduction adjusting layer 3 may be lower than the heat conduction rate of the adhesive layer 6. For example, the material of the heat conduction adjusting layer 3 may be a heat insulation material having a heat conduction rate lower than the heat conduction rate of the adhesive.

In other embodiments of the disclosure, when the heat conduction adjusting layer 3 is located in the non-circuit interconnection region of the substrate 211, or the heat conduction adjusting layer 3 is located at least on the surface of the circuit interconnection region of the substrate 211 in the chip unit 21 closest to the base 1, the heat conduction rate of the heat conduction adjusting layer 3 is greater than the heat conduction rate of the adhesive layer 6. For example, the material of the heat conduction adjusting layer 3 may be diamond, graphene, graphite, carbon nanotube, or combinations thereof, or, the material of the heat conduction layer 3 may be a metal or an alloy material of metal.

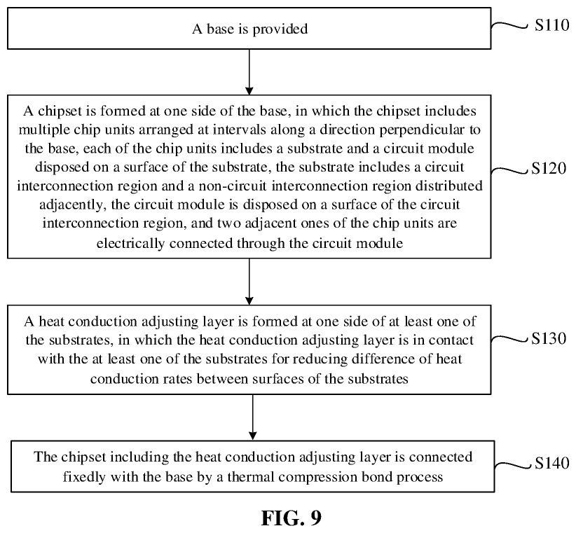

The disclosure further provides a forming method of a semiconductor structure for forming the semiconductor structure in any one of the above embodiments. FIG. 9 shows a flowchart of the forming method of a semiconductor structure of the disclosure. Referring to FIG. 9, the forming method may include S110 to S140.

In S110, a base is provided.

In S120, a chipset is formed at one side of the base. The chipset includes multiple chip units arranged at intervals along the direction perpendicular to the base. Each of the chip units includes a substrate and a circuit module located on the surface of the substrate. The substrate includes a circuit interconnection region and a non-circuit interconnection region distributed adjacently. The circuit module is located on the surface of the circuit interconnection region, and the adjacent chip units are electrically connected through the circuit module.

In S310, a heat conduction adjusting layer is formed on one side of at least one of the substrates. The heat conduction adjusting layer is in contact with at least one of the substrates, and is for reducing the difference of heat conduction rates between surfaces of the substrates.

In S140, the chipset including the heat conduction adjusting layer is connected fixedly with the base by thermal compression bond.

In the forming method of a semiconductor structure provided by the disclosure, multiple chip units 21 may be stacked in the vertical direction by thermal compression bond (TCB), which helps to improve the storage capacity. In the TCB process, due to the contact between the heat conduction adjusting layer 3 and the substrate 211 in the chip unit 21, by providing the heat conduction adjusting layer 3, the difference of heat conduction rates between the surfaces of different substrates 211 can be reduced, or the difference of heat conduction rates between surfaces in different regions in a same substrate 211 can be reduced. Therefore, the difference of heat conduction rates between the chip units 21 located in different layers can be reduced in the TCB welding process, thereby reducing the difference of temperatures between the surfaces of the chip units 21, reducing the probability of poor welding due to different welding temperatures between the different chip units 21, and improving the product yield. Alternatively, the difference of heat conduction rates between different regions of a same chip unit 21 can be reduced in the TCB welding process, thereby reducing the temperature difference on the surface of the same chip unit 21, reducing the probability of poor welding in different regions of the same chip unit 21, and further improving the product yield.

In some exemplary embodiments of the disclosure, forming the heat conduction adjusting layer 3 on one side of the substrate 211 includes forming a heat conduction adjusting layer 3 on one side of the substrate 211 before forming a circuit module 212. For example, a through silicon via (TSV) 43 may be formed in the chip unit 21. After the through silicon via (TSV) 43 is formed, a back surface of the chip unit 21 may be thinned to expose the top of the through-silicon path (TSV) 43. Subsequently, an insulating layer 5 may be formed on the back surface of the substrate 211 having the through silicon via (TSV) 43, and then the insulating layer 3 in contact with the substrate 211 may be formed after the heat conduction adjusting layer 5 is formed.

Specific details and beneficial effects of the forming method of a semiconductor structure of the disclosure have been described in detail in the corresponding embodiments of the semiconductor structure. The specific details may refer to the embodiments of the semiconductor structure, and will not be repeated herein.

In some embodiments of the disclosure, during the thermal compression bond process, the base 1 may be laid on an operation platform. The chip units 21 including the conductive structures 4 and the circuit modules 212 are stacked and laid in a direction perpendicular to the base 1. In this process, the conductive structure 4 located on the lowermost chip unit 21 may be brought into contact with the external circuit 11 in the base 1. Meanwhile, in two adjacent ones of the chip units, the conductive structure 4 located on the surface of the upper chip unit 21 may be brought into contact with the circuit module 212 of the lower chip unit 21. After the chip units 21 are laid, a non-conductive adhesive may be filled between the chip units 21. Next, the thermal compression bond process is performed on the structure composed of the base 1, the non-conductive adhesive, the conductive structures 4, the circuit modules 212 and the chip units 21, so as to form the semiconductor structure of the disclosure. During the thermal compression bond process, a pressure and a thermal compression temperature may be applied to the chip unit 21 farthest away from base 1 by a TCB head 7, so that the base 1, the non-conductive adhesive, the conductive structures 4, the circuit modules 212 and the chip units 21 may be firmly fixed together. It is to be noted that, the pressure applied by the TCB head 7 during the thermal compression bond process may be 80N, and the thermal compression temperature may be 200° C.˜ 300° C.

It is to be noted that, although each operation of the forming method of a semiconductor structure of the disclosure is described in a specific order in the accompany drawings, this does not require or imply that these operations must be performed in the specific order, or that all of the shown operations must be performed in order to achieve the desired results. Additionally or alternatively, some operations may be omitted, multiple operations may be merged into one operation for execution, and/or an operation may be decomposed into multiple operations for execution, etc.

The embodiments of the disclosure further provide a memory, which may include the semiconductor structure in any of the above embodiments. The specific details, the forming method and the beneficial effects of the semiconductor structure have been described in detail in the corresponding semiconductor structure and the forming method of the same, which are not repeated here.

For example, the memory may be a dynamic random access memory (DRAM), a static random access memory (SRAM), or other storage device, which is not enumerated herein.

Those skilled in the art may readily think of other embodiments of the disclosure after considering the specification and practicing the disclosure disclosed herein. The application is intended to cover any variant, uses or adaptive changes of the disclosure that follow general principles of the disclosure and include common knowledge or common techniques in the art not disclosed in the disclosure. The specification and the embodiments are only regarded as illustratively, and the true scope and spirit of the disclosure are pointed out by the appended claims.

What is claimed is:

1. A semiconductor structure, comprising:
a base;
a chipset disposed at one side of the base and comprising multiple chip units arranged at intervals along a direction perpendicular to the base, wherein each of the chip units comprises a substrate and a circuit module disposed on a surface of the substrate, the substrate comprises a circuit interconnection region and a non-circuit interconnection region distributed adjacently, the circuit module is disposed on a surface of the circuit interconnection region, and two adjacent ones of the chip units are electrically connected through the circuit module; and
a heat conduction adjusting layer in contact with at least one of the substrates for reducing difference of heat conduction rates between surfaces of the substrates.

2. The semiconductor structure of claim 1, wherein the heat conduction adjusting layer is disposed in the circuit interconnection region of the substrate, and a heat conduction rate of the heat conduction adjusting layer is lower than a heat conduction rate of the circuit interconnection region of the substrate.

3. The semiconductor structure of claim 1, wherein the heat conduction adjusting layer is disposed in the non-circuit interconnection region of the substrate, and a heat conduction rate of the heat conduction adjusting layer is greater than a heat conduction rate of the non-circuit interconnection region of the substrate.

4. The semiconductor structure of claim 1, wherein the heat conduction adjusting layer comprises a first adjusting part and a second adjusting part, the first adjusting part is located on a surface of the circuit interconnection region of the substrate, a heat conduction rate of the first adjusting part is lower than a heat conduction rate of the circuit interconnection region, the second adjusting part is located on a surface of the non-circuit interconnection region of the substrate, and a heat conduction rate of the second adjusting part is greater than a heat conduction rate of the non-circuit interconnection region of the substrate.

5. The semiconductor structure of claim 1, wherein the heat conduction adjusting layer is located at least on a surface of the circuit interconnection region of the substrate in the chip unit farthest away from the base, and a heat conduction rate of the heat conduction adjusting layer is lower than a heat conduction rate of the circuit interconnection region of the substrate in the chip unit farthest away from the base.

6. The semiconductor structure of claim 1, wherein the heat conduction adjusting layer is located at least on a surface of the circuit interconnection region of the substrate in the chip unit closest to the base, and a heat conduction rate of the heat conduction adjusting layer is greater than a heat conduction rate of the circuit interconnection region of the substrate in the chip unit closest to the base.

7. The semiconductor structure of claim 1, wherein the heat conduction adjusting layer comprises a third adjusting part and a fourth adjusting part, the third adjusting part is located at least on a surface of the circuit interconnection region of the substrate in the chip unit farthest away from the base, a heat conduction rate of the third adjusting part is lower than a heat conduction rate of the circuit interconnection region of the substrate in the chip unit farthest away from the base; the fourth adjusting part is located at least on a surface of the circuit interconnection region of the substrate in the chip unit closest to the base, and a heat conduction rate of the fourth adjusting part is greater than a heat conduction rate of the circuit interconnection region of the substrate in the chip unit closest to the base.

8. The semiconductor structure of claim 1, wherein the base comprises an external circuit, the semiconductor structure further comprises:
a conductive structure located between the chipset and the base, wherein one end of the conductive structure is electrically connected with any one of the chip units, and another end is connected with the external circuit of the base.

9. The semiconductor structure of claim 1, wherein a concave part depressed inwards in the direction perpendicular to the substrate is disposed in a surface of the substrate facing away from the base, and the heat conduction adjusting layer is located at least in the concave part.

10. The semiconductor structure of claim 1, wherein the heat conduction adjusting layer is disposed on a surface of the substrate facing away from the base.

11. The semiconductor structure of claim 2, further comprising:
an adhesive layer located between two adjacent ones of the chip units and filling up a gap between the two adjacent chip units, wherein the heat conduction rate of the heat conduction adjusting layer is lower than a heat conduction rate of the adhesive layer.

12. The semiconductor structure of claim 5, further comprising:
an adhesive layer located between two adjacent ones of the chip units and filling up a gap between the two adjacent chip units, wherein the heat conduction rate of the heat conduction adjusting layer is lower than a heat conduction rate of the adhesive layer.

13. The semiconductor structure of claim 3, further comprising:
an adhesive layer located between two adjacent ones of the chip units and filling up a gap between the two adjacent chip units, wherein the heat conduction rate of the heat conduction adjusting layer is greater than a heat conduction rate of the adhesive layer.

14. The semiconductor structure of claim 6, further comprising:
an adhesive layer located between two adjacent ones of the chip units and filling up a gap between the two adjacent chip units, wherein the heat conduction rate of the heat conduction adjusting layer is greater than a heat conduction rate of the adhesive layer.

15. A forming method of a semiconductor structure, comprising:
providing a base;
forming a chipset at one side of the base, wherein the chipset comprises multiple chip units arranged at intervals along a direction perpendicular to the base, each of the chip units comprises a substrate and a circuit module disposed on a surface of the substrate, the substrate comprises a circuit interconnection region and a non-circuit interconnection region distributed adjacently, the circuit module is disposed on a surface of the circuit interconnection region, and two adjacent ones of the chip units are electrically connected through the circuit module;
forming a heat conduction adjusting layer at one side of at least one of the substrates, wherein the heat conduction adjusting layer is in contact with the at least one of the substrates for reducing difference of heat conduction rates between surfaces of the substrates; and
connecting the chipset comprising the heat conduction adjusting layer fixedly with the base by a thermal compression bond process.

16. The forming method of claim 15, wherein forming a heat conduction adjusting layer at one side of at least one of the substrates comprises:
forming a concave part depressed inwards in the direction perpendicular to the substrate in a surface of the substrate facing away from the base; and
forming the heat conduction adjusting layer at least in the concave part.

17. The forming method of claim 15, wherein forming a heat conduction adjusting layer at one side of at least one of the substrates comprises:
forming the heat conduction adjusting layer on a surface of the substrate facing away from the base.

18. The forming method of claim 15, wherein forming a heat conduction adjusting layer at one side of the substrate comprises:
forming the heat conduction adjusting layer at one side of the substrate before forming the circuit module.

19. A memory comprising the semiconductor structure of claim 1.
